(19) United States
(12) Patent Application Publication
(10) Pub. No.: US 2006/0071352 A1
(43) Pub. Date: Apr. 6, 2006

(54) Thin film transistors and methods of manufacture thereof

(76) Inventors: Carl Glasse, Redhill (GB); Stanley D Brotherton, Forest Row (GB)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/533,020

(22) PCT Filed: Oct. 14, 2003
(86) PCT No.: PCT/IB03/04539

§ 371 Date: Apr. 27, 2005

(30) Foreign Application Priority Data
Oct. 30, 2002 (GB) 0225205.4

(51) Int. Cl. H01L 27/10

(52) U.S. Cl. 257/900

(57) ABSTRACT

A polycrystalline silicon GOLDD TFT with a gate (10) overlying its channel (11) is fabricated by using the gate (10) as a mask during a first dopant implantation step. Spacers (13, 14) are then formed adjacent to the gate (10), which comprise portions of a thin metallic layer (19) which are defined by fillets (17) in an etching process. The spacers and gate are then used as a mask for doping source and drain regions, thereby providing a self-aligned fabrication technique.

This invention relates to a thin film transistor (TFT), which may be used for example in an active matrix liquid crystal display (AMLCD) or other flat panel display.

As well known in the art, TFTs are employed in AMLCDs and other flat panel displays to control the state of each pixel of the display. They may be fabricated on inexpensive insulating substrates such as glass or plastics material, utilising polycrystalline semiconductor films, as described for example in U.S. Pat. No. 5,130,829.

A conventional TFT comprises of an insulating layer such as silicon dioxide, with a polysilicon channel formed on the silicon dioxide layer, extending between heavily doped source and drain regions. The polysilicon layer may be formed from a layer of amorphous silicon by an annealing process, which may be performed using a excimer laser, as described in J. Appl. Phys. 82 (8) 15 Oct. 1997 S. D. Brotherton, D. J. McCulloch et al. The channel is overlaid by an insulating layer which in turn is overlaid by a gate region. The heavily doped source and drain regions may be produced by ion implantation in the polysilicon layer, using the gate as a mask so as to achieve a self aligned structure.

A problem with this conventional arrangement is that a hot carrier instability can occur at high drain bias, for example >10 v, which can degrade performance of the TFT particularly in a AMLCD in which such voltages are commonly used. Also, leakage current may occur in the off state of the transistor due to defects at the region of the polysilicon channel and the heavily doped drain region. The defects may also reduce channel mobilities in the on state of the transistor.

It has been proposed to address these issues by including a lightly doped drain (LDD) region between the undoped polysilicon channel and the heavily doped drain region in order to relieve the drain field. U.S. Pat. No. 5,786,241 discloses a polysilicon channel TFT with a LDD region between the undoped polysilicon channel under the gate and the heavily doped drain region. A corresponding lightly doped region is also formed between the heavily doped source and the undoped channel. The LDD regions reduce the peak field and reduce the leakage current in the off state. The LDD regions are fabricated by lightly doping by ion implantation using the gate as a mask. Spacer regions of undoped insulating silicon dioxide are then formed on opposite sides of the gate and then the polysilicon layer is heavily doped by ion implantation using both the gate and the spacers as the mask, with the result that LDD regions are formed under the spacer regions between the heavily doped source and drain regions and the undoped channel under the gate.

A disadvantage of these LDD regions is that they deleteriously affect the channel current in the on state.

It has also been proposed to arrange the gate of a TFT so that it overlaps the LDD regions to provide gate overlapped LDD or GOLDD regions. The gate applies a field to the LDD regions as a result of the overlapping configuration, which has the advantage of reducing their resistance in the on state of the transistor. Reference is directed to “The Technology and Application of Laser Crystallised Poly-Si TFTs”, S. D. Brotherton, J. R. Ayres et al, Electrochemical Soc. Proc. Vol. 98-22 (1998) pp. 25-43. This discusses the characteristics of GOLDD TFTs and proposes that the fabrication of the GOLDD regions is carried out by firstly forming the LDD regions in the channel of the TFT and then overlying the gate to form the GOLDD configuration.

The present invention seeks to provide a TFT which has a GOLDD regions that can be fabricated by self-aligned (SA) techniques.

According to the invention there is provided a TFT comprising a polycrystalline silicon channel extending between a source and drain, a gate overlying the channel, and of a thickness to define an upstanding gate side wall, an LDD region, and a spacer overlying the LDD region, wherein the spacer comprises a conductive region that both overlies the LDD region and extends along the upstanding gate side wall.

Preferably, the conductive region comprises a layer that is thinner than the thickness of the gate and has a first portion overlying the LDD region and a second portion extending along the upstanding side wall of the gate.

The invention also includes a method of fabricating a polycrystalline silicon channel TFT with a gate overlying the channel, having an upstanding gate side wall, the method comprising:

(a) providing a gate separated from a polycrystalline silicon layer by an insulating layer;

(b) implanting a dopant into the polycrystalline silicon layer using the gate as a mask;

(c) forming a spacer after step (b) adjacent to the gate that comprises a conductive region which overlies the polycrystalline silicon layer and extends along the gate side wall; and

(d) implanting a dopant into the polycrystalline silicon layer using the gate and the spacer as a mask to form a source or drain region, such that the spacer overlies an LDD region in the polycrystalline silicon layer between the source or drain region and the channel.

The spacer may be formed by depositing a layer of conductive material over the channel and the gate, and selectively etching the deposited layer of conductive material to form the spacer with a first portion overlying the channel and a second portion extending along on the side wall of the gate. The deposited layer may have a thickness which is less than that of the gate. It may be a non-conformal layer of conductive material. In a preferred embodiment, it comprises a metallic layer deposited by sputtering.

The selective etching of the conductive layer may be carried out by forming a fillet overlying the first portion thereof, and selectively etching the layer where not protected by the fillet.

A further layer, which may be a conformal Si containing layer, may be deposited on said conductive layer, for example by PECVD, and selectively etched to form the fillet.

In order that the invention may be more fully understood, the prior art and embodiments of the invention will now be described with reference to the accompanying drawings in which:

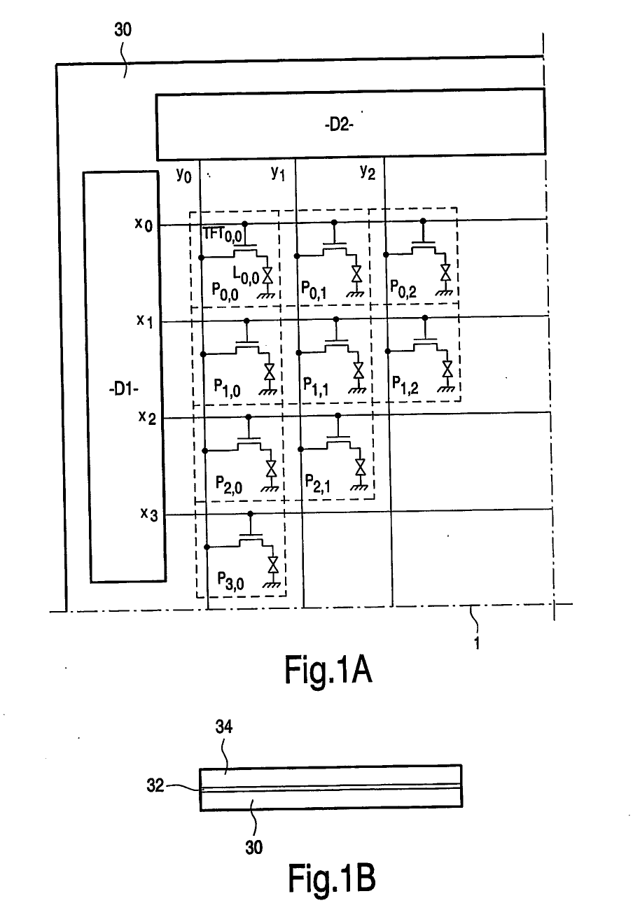

FIGS. 1A and 1B are schematic illustrations of a known active panel and a known AMLCD, respectively, incorporating TFTs;

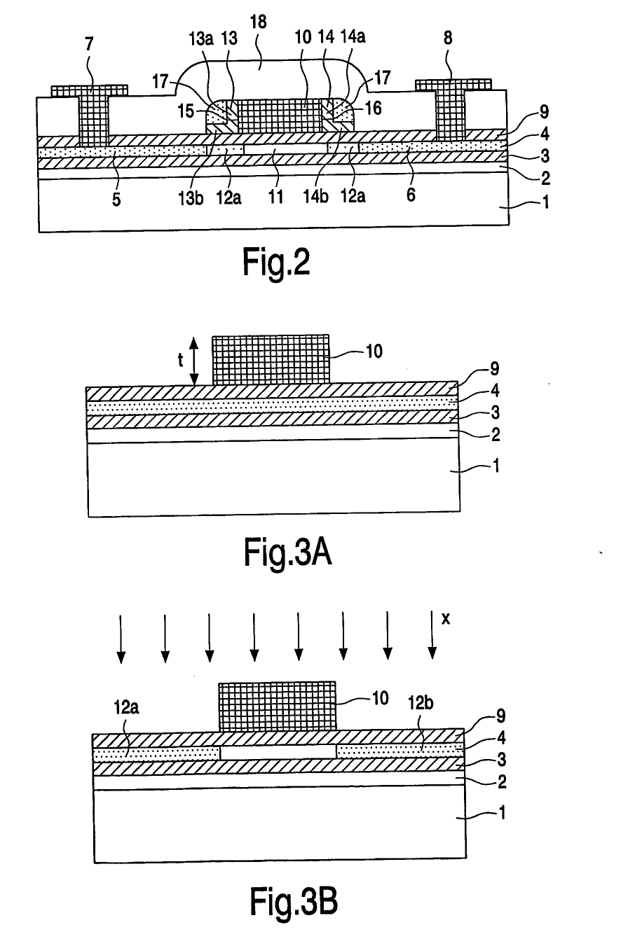

FIG. 2 is a schematic cross-sectional view of a TFT in accordance with an embodiment of the invention; and

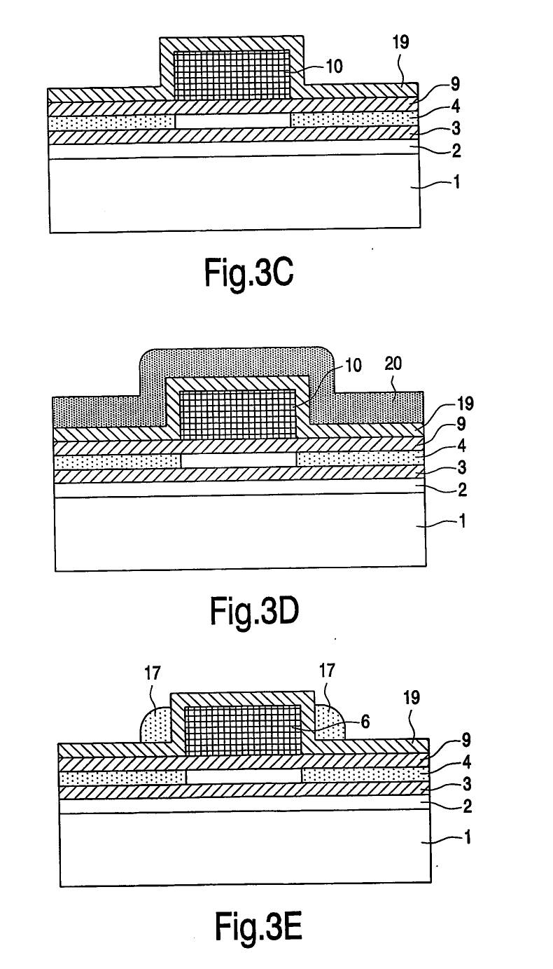

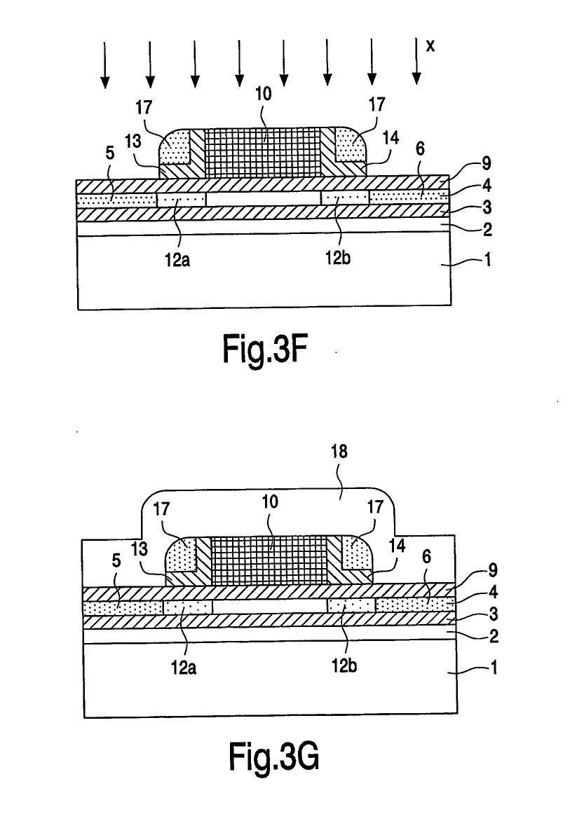

FIGS. 3A-3G are schematic cross-sectional views of process steps carried out in order to fabricate the TFT illustrated in FIG. 2

Referring to FIG. 1A, an active plate 30 of an AMLCD panel comprises a planar support 1 that may be optically transparent, on which an active switching matrix of LCD pixels P is provided, in a manner well known per se in the art. The pixels P_{x,y} are arranged in a rectangular x, y array and are operated by x and y driver circuits D1, D2. As is well known, an AMLCD panel may be formed by sandwiching a layer of liquid crystal material 32 between the active plate 30 and a passive plate 34, as shown schematically in FIG. 1B.

Considering the pixel P_{0,0} by way of example, it includes a liquid crystal display element L_{0,0} which is switched between different optical transmisivities by means of TFT_{0,0} that has its gate connected to drive line x₀ and its source coupled to driver line y₀. The drain of the TFT is connected to the display element L_{0,0} and by applying suitable voltages to the lines x₀, y_{0′} transistor TFT_{0,0} can be switched on and off and thereby control the operation of the LCD element L_{0,0}. It will be understood that each of the pixels P of the display is of a similar construction and that the pixels can be scanned row by row on operation of the x and y driver circuits D1, D2 in a manner well known per se.

FIG. 2 illustrates a TFT in accordance with the invention, which may be used in an active plate or AMLCD of the configurations shown in FIGS. 1A and 1B. The TFT is shown in section, formed on the glass or plastics substrate 1, and comprises a layer 2 of silicon nitride, formed by PECVD, overlaid by a layer 3 of silicon dioxide, also deposited by PECVD in the manner well known in the art.

The TFT has a channel 11 formed in a layer 4 of polysilicon, deposited initially as amorphous silicon and then annealed into a polycrystalline form, which is heavily n⁺ doped to form source and drain regions 5, 6, that have metal ohmic contacts 7, 8. The polycrystalline layer 4 is overlaid by a silicon dioxide layer 9 which itself is overlaid by a conductive gate region 10 which may be formed of a metal such as Al or Ti or an alloy thereof such as AI(1% Ti) alloy.

The polysilicon layer 4 includes an undoped channel region 11 underlying the gate 9 together with LDD regions 12a, 12b that are n⁻ doped, between the heavily doped n⁺ regions 5, 6 and the undoped region 11.

Spacer regions 13, 14 overlie the LDD regions 12a, 12b. The spacer regions 13, 14 are made of an electrically conductive material, a metal in this example, deposited in a layer that extends along both the oxide layer 9 above the LDD regions 12a, 12b and also along upstanding side walls, 15, 16 of the gate 10. Thus, as shown in FIG. 2, the spacer regions include first portions 13a, 14a, which extend along the upwardly extending side walls 15, 16 of the gate 10 and second portions 13b, 14b that extend along the surface of the insulating oxide layer 9, so as to overlie the LDD regions 12a, 12b. Fillets 17 of material such as n⁺ Si or silicon dioxide overlie the spacer regions 13b, 14b. The entire device is covered by an insulating layer 18 of silicon dioxide.

A method of fabricating the device of FIG. 2 will now be described in more detail with reference to FIG. 3. Referring to FIG. 3A, the glass substrate 1 is prepared by depositing a layer of silicon nitride 2 by conventional PECVD techniques to a thickness of 100 nm. Thereafter, a layer of silicon dioxide is grown to a thickness of 300-400 nm.

Then, layer 4 of amorphous silicon is deposited by PECVD to a thickness of 40 nm. The amorphous silicon layer 4 is annealed, for example by an excimer laser so that the layer 4 is converted into polysilicon. Thereafter, a silicon dioxide layer 5 is grown to a thickness of 40-150 nm. For further details reference is directed to J. Appl. Phys. 82 (8) 15 Oct. 1997 S. D. Brotherton, D. J. McCulloch et al.

Thereafter, a metallic layer is deposited to a thickness t of 0.5-1 μm by sputter deposition. The resulting metallic layer is then patterned using conventional photolithographic and etching techniques to define the gate region 10 as shown in FIG. 3A.

Referring to FIG. 3B, the gate region 10 is used as a mask to allow a relatively low intensity of dopant to be deposited in the layer 4, for the purpose of forming the LDD regions 12a, 12b. The region of layer 4 beneath the mask provided by gate 10, remains undoped during this process. The dopant may comprise P ions to achieve a dopant concentration of 3E12-3E13 atoms per cm⁻².

Referring to FIG. 3C, a thin metallic layer 19 of for example Cr is deposited over the upper surface of the device by a standard non-conformal technique such as sputtering, to a thickness of 50-150 nm. The thickness of the layer 19 is substantially less than the thickness t of the gate region 10 and so the sputtering process need not over-heat the substrate 1 and damage it.

Referring to FIG. 3D a conformal layer 20 of n⁺ Si for example is deposited to a thickness typically of 0.5 μm-1.0 μm by sputtering or PECVD and is then subject to an anisotropic or planar etch, for example Reactive Ion Etching (RIE), so as to provide the electrically insulating fillets 17.

Thereafter, the metallic layer 19 is etched to remove regions of metal that are not covered by the fillets 17. The resulting configuration shown in FIG. 3F. A suitable wet etchant for the thin Cr layer 19 is an aqueous mixture of ammonium hexa-nitrato-cerate(IV) and nitric acid. However, other metals or alloys may be used for the layer 19, which may be more suitably etched by other wet or dry enchants, as will be evident to those skilled in the art. The etching process results in electrically conductive spacer regions 13, 14 being disposed on opposite sides of the gate electrode 10, with regions 13a, 14a extending along the upward side edges 15, 16 of the gate region 10, and regions 13b, 14b extending along the surface regions 21, 22 of the oxide layer 9.

The spacer regions 13, 14 together with fillets 17 are used as a mask during implantation of the heavily doped source and drain regions 5, 6. To this end, P ions are directed to the substrate in the direction of arrows X in order to become implanted in the layer 4 so as to form the source and drain regions 5, 6. The regions 12a, 12b that were previously lightly doped are masked by the spacer regions 13, 14 and the fillets 17. Thus, a GOLDD configuration is achieved. The conductive regions 13, 14 are in electrical contact with the gate region 10 so as to extend the lateral extent of the gate; the regions 13, 14 form part of the gate and overlap the LDD regions 12a, 12b.

Thereafter, as shown in FIG. 3G, a silicon dioxide passivation layer 18 is deposited, for example to a thickness of 300 nm by PECVD. Thereafter, the metallic source and drain contacts 7, 8 (shown in FIG. 2) are deposited by conventional patterning and deposition techniques so as to allow external electrical connection to the heavily doped source and drain regions 5, 6.

With conventional TFTs hot carrier instability can occur at drain bias >10V, while TFTs according to the invention can be stable up to 20V.

An advantage of fabrication techniques described herein is that they made use standard deposition techniques readily available in modern TFT production, namely sputter deposition and CVD. Sputter deposition can be used for the metal layer 19 that forms the spacer regions 13, 14 and PECVD deposition can be used for the Si based layer 20 that forms the fillets 17. Thus, the described TFT can be produced by a simple modification of processes already used for the TFT production without the need to introduce more complex deposition techniques.

From reading the present disclosure, other variations and modifications will be apparent to persons skilled in the art. Such variations and modifications may involve equivalent and other features which are already known in the design, manufacture and use of electronic devices comprising TFTs and other semiconductor devices and component parts thereof and which may be used instead of or in addition to features already described herein. Although Claims have been formulated in this Application to particular combinations of features, it should be understood that the scope of the disclosure of the present invention also includes any novel features or any novel combination of features disclosed herein either explicitly or implicitly or any generalisation thereof, whether or not it relates to the same invention as presently claimed in any Claim and whether or not it mitigates any or all of the same technical problems as does the present invention. The Applicants hereby give notice that new Claims may be formulated to such features and/or combinations of such features during the prosecution of the present Application or of any further Application derived therefrom.

1. A TFT comprising a polycrystalline silicon channel (11) extending between a source (5) and drain (6), a gate (10) overlying the channel, and of a thickness to define an upstanding gate side wall (15, 16), a LDD region (12a, 12b), and a spacer (13, 14) overlying the LDD region, wherein the spacer comprises a conductive region (13a, 13b, 14a, 14b) that both overlies the LDD region and extends along the upstanding gate side wall.

2. A TFT according to claim 1 wherein the conductive region (13a, 13b, 14a, 14b) comprises a layer that is thinner than the thickness of the gate (10) and has a first portion (13b, 14b) overlying the LDD region and a second portion (13a, 14a) extending along the upstanding side wall (15, 16) of the gate.

3. A TFT according to claim 2 wherein the conductive region (13, 14) comprises a layer of conductive material.

4. A TFT according to claim 3 wherein the layer (13, 14) is a metallic layer deposited by sputtering.

5. A TFT according to claim 3 wherein the layer (13, 14) comprises a doped semiconductor material.

6. A TFT according to any one of claims 2 to 5 including a fillet (17) over the first portion of the conductive region.

7. An active plate (30) for an active matrix display, including a TFT according to any preceding claim.

8. An active matrix liquid crystal display comprising an active plate according to claim 7, a passive plate (34), and a layer of liquid crystal material (32) sandwiched between the active and passive plates.

9. A method of fabricating a polycrystalline silicon channel TFT with a gate (10) overlying its channel (11), having an upstanding gate side wall (15, 16), the method comprising the steps of:
(a) providing a gate (10) separated from a polycrystalline silicon layer (4) by an insulating layer (9);
(b) implanting a dopant into the polycrystalline silicon layer (4) using the gate (10) as a mask;
(c) forming a spacer (13, 14) after step (b) adjacent to the gate (10) that comprises a conductive region which overlies the polycrystalline silicon layer and extends along the gate side wall (15, 16); and
(d) implanting a dopant into the polycrystalline silicon layer (4) using the gate (10) and the spacer (13, 14) as a mask to form a source or drain region (5 or 6), such that the spacer (13, 14) overlies an LDD region (12a, 12b) in the polycrystalline silicon layer (4) between the source or drain region (5 or 6) and the channel (11).

10. A method according to claim 9 wherein step (c) comprises includes depositing a layer (13, 14) of conductive material over the polycrystalline silicon layer and the gate, and selectively etching the deposited layer of conductive material to form the spacer with a first portion overlying the polycrystalline silicon layer and a second portion extending along on the side wall of the gate.

11. A method according to claim 10 including depositing the layer of conductive material to a thickness which is less than that of the gate.

12. A method according to claim 10 or 11 including depositing the conductive material in a non-conformal layer.

13. A method according to any one of claims 10 to 12 including depositing the layer by sputtering.

14. A method according to any one of claims 10 to 13 including depositing said layer as a metallic layer.

15. A method according claim 10 or 11 wherein the selective etching of the conductive layer is carried out by forming a fillet (17) over the first portion thereof, and selectively etching the layer where not protected by the fillet.

16. A method according to claim 13 including depositing a further layer on said conductive layer, and selectively etching the further layer to form the fillet therefrom.

17. A method according to claim 16 including depositing the further layer as a conformal layer.

18. A method according to claim 16 including depositing the further layer as a Si containing layer.

19. A method according to any one of claims 15 to 18 including depositing the further layer by CVD.
